(19) United States
(12) Patent Application Publication
(10) Pub. No.: US 2006/0141700 A1
(43) Pub. Date: Jun. 29, 2006

(54) Method for fabricating semiconductor memory device having recessed storage node contact plug

(75) Inventor: Ki-Won Nam, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/321,634

(22) Filed: Dec. 28, 2005

(30) Foreign Application Priority Data
Dec. 28, 2004 (KR) 2004-0114018

(51) Int. Cl. H01L 21/8242; H01L 21/20

(52) U.S. Cl. 438/243; 438/386

(57) ABSTRACT

A semiconductor memory device and a method for fabricating a semiconductor memory device are provided. The method includes forming an inter-layer insulation layer having a storage node contact hole on a substrate; forming a pair of storage node contact spacers on sidewalls of the storage node contact hole; forming a storage node contact plug surrounded by the storage node contact spacers inside the storage node contact hole; recessing a surface of the storage node contact plug to a predetermined depth to expose upper portions of the storage node contact spacers; forming an etch stop insulation layer on the surface of the storage node contact plug and the inter-layer insulation layer; forming a trench opening a predetermined portion of the storage node contact plug and the storage node spacers by etching the etch stop insulation layer; forming a bottom electrode on the trench; and sequentially forming a dielectric layer and a top electrode on the bottom electrode.

### FIELD OF THE INVENTION

The present invention relates to a method for fabricating a semiconductor device; and more particularly, to a method for fabricating a semiconductor memory device.

### DESCRIPTION OF RELATED ARTS

As a minimum line width of a semiconductor device has been decreased and a degree of integration of a semiconductor device has also been increased, an area in which a capacitor is formed has been decreased. Accordingly, although the area in which the capacitor is formed has been decreased, the capacitor inside of a cell should ensure the least required capacitance per cell.

Thus, there have been suggested various methods to form a capacitor that has high capacitance within the limited area. One suggested method is to form a dielectric layer with a high electric permittivity level such as Ta₂O₅, Al₂O₃ or HfO₂, replacing a silicon dioxide layer having a dielectric constant (ε) of 3.8 and a nitride layer having a dielectric constant (ε) of 7. Another suggested method is to effectively increase an area of a bottom electrode by forming the bottom electrode with a three-dimensional structure such as a cylinder structure or a concave structure, or by increasing the effective surface area of the bottom electrode by 1.7 fold to 2 fold through growing metastable polysilicon (MPS) grains on the surface of the bottom electrode. Also, a metal-insulator-metal (MIM) method for forming a bottom electrode and a top electrode by using a metal layer has been suggested.

In a dynamic random access memory (DRAM) device with 128 M bits, a method for fabricating a semiconductor memory device having a MIM type capacitor with a typical concave type bottom electrode formed of titanium nitride (TiN) will be described hereinafter.

FIGS. 1A and 1B are cross-sectional views briefly illustrating a method for fabricating a conventional semiconductor device.

As shown in FIG. 1A, an inter-layer insulation layer 12 is formed on an upper portion of a substrate 11. Then, the inter-layer insulation layer 12 is etched, thereby forming a storage node contact hole (not shown) opening a surface of the substrate 11.

Next, a plurality of storage node contact spacers 14 are formed on sidewalls of the storage node contact hole (not shown). Then, a storage node contact plug 13 is buried into the storage node contact hole (not shown) provided with the storage node contact spacers 14. Herein, the storage node contact spacers 14 are formed by using a silicon nitride layer and the storage node contact plug 13 is formed by using polysilicon.

Next, an etch stop insulation layer 15 is formed on the inter-layer insulation layer 12 including the storage node contact plug 13 and then, an insulation layer 16 for a storage node is formed on the etch stop insulation layer 15. Herein, the etch stop insulation layer 15 is formed by using a silicon nitride layer and the insulation layer 16 is formed by using a silicon oxide based layer.

Next, the insulation layer 16 and the etch stop insulation layer 15 are sequentially subjected to a dry etching process, thereby forming a trench 17 opening an upper portion of the storage node contact plug 13.

As shown in FIG. 1B, prior to forming a titanium nitride (TiN) bottom electrode, it is required to form a barrier metal layer in order to form the TiN bottom electrode. Thus, to form the barrier metal layer, titanium (Ti) is deposited on an entire surface including the trench 17 through a physical vapor deposition (CVD) method or a chemical vapor deposition (CVD) method. Afterwards, titanium silicide (TiSiₓ) 18 which is the barrier metal layer is formed through an annealing process and then, non-reacted Ti is removed through a wet etching process.

As described above, by forming TiSiₓ 18, it is possible to reduce a resistance of a layer which the storage node contact plug 13 is contacted with the TiN bottom electrode.

After forming TiSiₓ 18, TiN is deposited on the entire surface including the trench 17 and then, TiN on an upper portion of the insulation layer 16 is selectively removed. Thus, the aforementioned TiN bottom electrode 19 connected to the storage node contact plug 13 inside the trench 17 is formed.

Next, a dielectric layer 20 and a TiN top electrode 21 are sequentially formed on the TiN bottom electrode 19, thereby forming a capacitor.

However, at the step of etching the etch stop insulation layer 15 formed by using the silicon nitride layer during forming the trench 17, a damage in one of the storage node contact spacers 14 is generated. In more details, the storage node spacers 14 formed by using the silicon nitride layer similar to the formation of the etch stop insulation layer 15 are excessively etched due to an overlay between the storage node contact plug 13 and the TiN bottom electrode 19, thereby generating the damage in one of the storage node contact spacers 14. Due to the damage in one of the storage node contact spacers 14, only the storage node contact spacer 14 is additionally and excessively etched in a thickness ranging from approximately 1,000 Å to approximately 1,500 Å in a narrow space of the surroundings of the storage node contact plug 13 and thus, an opening 22 is generated (refer to FIG. 1A).

In such a situation which the opening 22 is generated, the TiN bottom electrode 19 is formed through the deposition and the etch of TiN with step coverage of 50%, and the dielectric layer 20 and the TiN top electrode 21 are formed. At this time, a space 23 into which TiN used for forming the TiN top electrode 21 is deposited is blocked or very narrow. Due to the above mentioned reason, the TiN top electrode 21 cannot be properly deposited and thus, a cruspidal structure 24 is generated on the dielectric layer 20 and the TiN top electrode 21.

Accordingly, as a structural defect of the capacitor which works as a leakage current source of the capacitor is formed, a leakage current property of the capacitor is degraded.

### SUMMARY OF THE INVENTION

It is, therefore, an object of the present invention to provide a method for fabricating a semiconductor memory device capable of removing a leakage current source of a capacitor generated by an opening formed due to a damage in a storage node contact spacer at the step of etching an etch stop insulation layer.

In accordance with one aspect of the present invention, there is provided a method for fabricating a semiconductor memory device, including: forming an inter-layer insulation layer having a storage node contact hole on a substrate; forming a pair of storage node contact spacers recess to a predetermined thickness on sidewalls of the storage node contact hole; forming a storage node contact plug surrounded by the storage node contact spacers inside the storage node contact hole; recessing a surface of the storage node contact plug to a predetermined depth to expose upper portions of the storage node contact spacers; forming an etch stop insulation layer on the surface of the storage node contact plug and the inter-layer insulation layer; forming a trench opening a predetermined portion of the storage node contact plug and the storage node spacers by etching the etch stop insulation layer; forming a bottom electrode on the trench; and sequentially forming a dielectric layer and a top electrode on the bottom electrode.

In accordance with anther aspect of the present invention, there is provided a method for fabricating a semiconductor memory device, including: forming an inter-layer insulation layer having a storage node contact hole on a substrate; forming a pair of storage node contact spacers on sidewalls of the storage node contact hole; forming a storage node contact plug surrounded by the storage node contact spacers inside the storage node hole; recessing a surface of the storage node contact plug in a predetermined depth to expose upper portions of the storage node contact spacers; forming an etch stop insulation layer and an insulation layer for a storage node on the recessed storage node contact plug and the inter-layer insulation layer; sequentially performing a dry etching process on the insulation layer and on the etch stop insulation layer to form a trench opening the storage node contact spacers and the storage node contact plug; forming a bottom electrode on the trench; and sequentially forming a dielectric layer and a top electrode on the bottom electrode.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A and 1B are cross-sectional views briefly illustrating a method for fabricating a conventional semiconductor memory device; and

FIGS. 2A to 2E are cross-sectional views illustrating a method for fabricating a semiconductor memory device in accordance with a specific embodiment of the present invention.

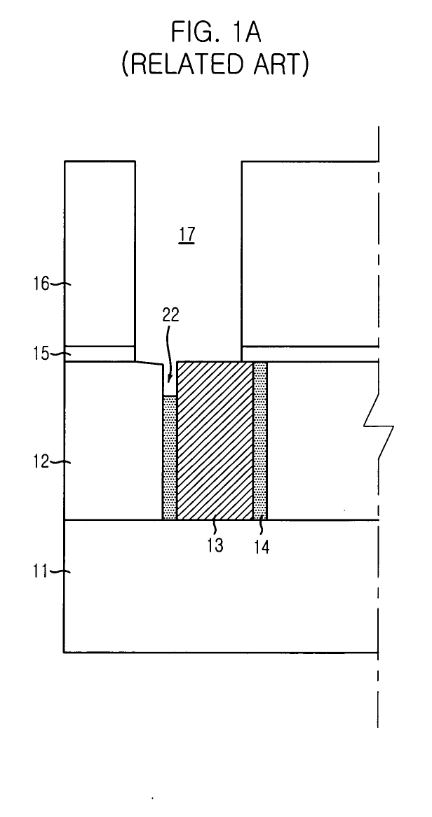

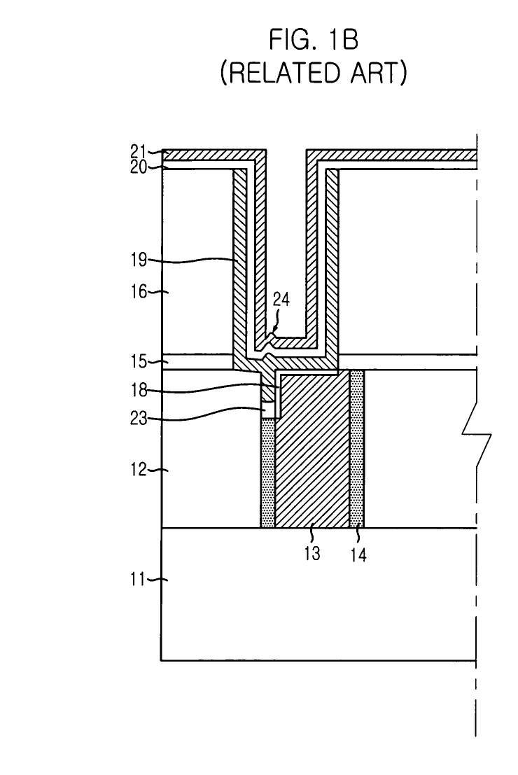

### DETAILED DESCRIPTION OF THE INVENTION

Hereinafter, detailed descriptions of preferred embodiments of the present invention will be provided with reference to the accompanying drawings.

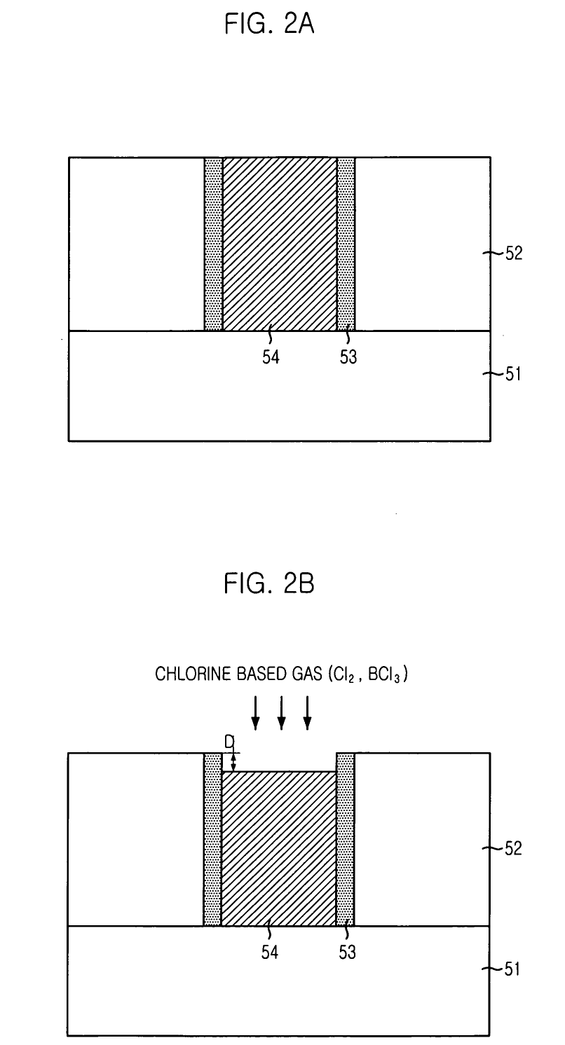

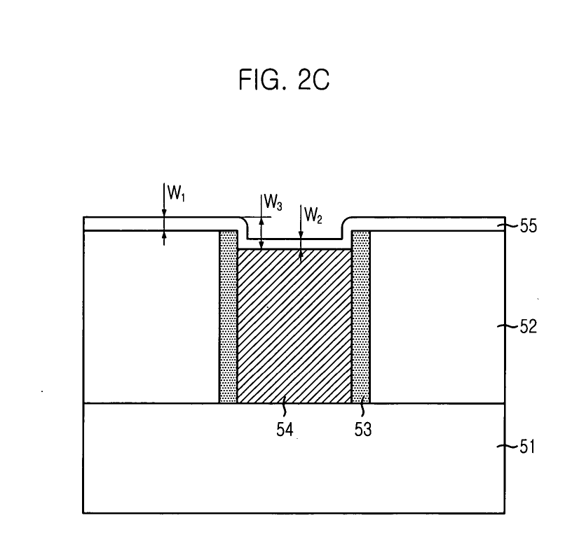

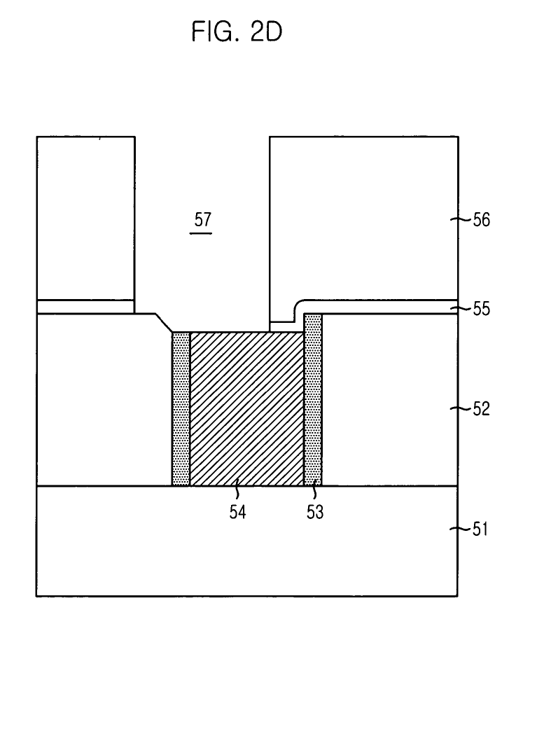

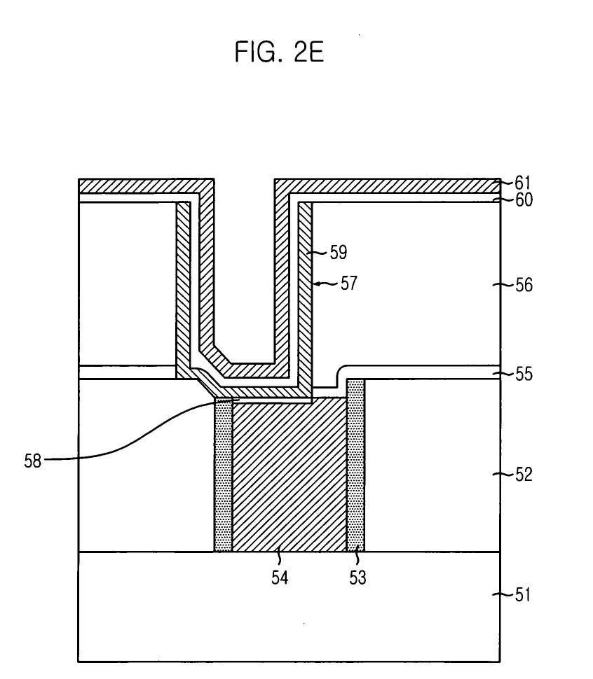

FIGS. 2A to 2E are cross-sectional views illustrating a method for fabricating a semiconductor memory device in accordance with a second embodiment of the present invention.

As shown in FIG. 2A, an inter-layer insulation layer 52 is formed on an upper portion of a substrate 51. At this time, although not shown, prior to forming the inter-layer insulation layer 52, as well known, various constitution elements including transistors and bit lines are formed and accordingly, the inter-layer insulation layer 52 may be formed in a multiple structure.

Next, a contact mask (not shown) using a photoresist layer is formed on the inter-layer insulation layer 52. Then, the inter-layer insulation layer 52 is etched by using the contact mask as an etch barrier, thereby forming a storage node contact hole (not shown) opening a portion of the substrate 51. At this time, the portion of the substrate 51 in which the storage node contact hole is opened may be a source/drain junction region.

Next, a plurality of storage node contact spacers 53 are formed on sidewalls of the storage node contact hole. At this time, in more details about the formation of the storage node contact spacers 53, a silicon nitride layer (Si₃N₄) layer is deposited on an entire surface including the storage node contact hole. Afterwards, an etch-back process is performed to expose a surface of the substrate 51, thereby forming the storage node contact spacers 53 on the sidewalls of the storage node contact hole.

Next, a storage node contact plug 54 is buried inside the storage node contact hole provided with the storage node contact spacers 53. At this time, as for the formation of the storage node contact plug 54, a polysilicon layer is deposited on an entire surface of the above resulting structure until the storage node contact hole provided with the storage node contact spacers 53 is filled and afterwards, a predetermined portion of the polysilicon layer is polished through a touch chemical mechanical polishing (TCMP) process. Then, a dry etch-back process is continuously performed and thus, the storage node contact plug 54 is formed.

As shown in FIG. 2B, a recessing process recessing the storage node contact plug 54 in a predetermined thickness is employed.

At this time, the recessing process is performed through a dry etching process which can selectively etch the storage node contact plug 54 faster than the storage node contact spacers 53.

For instance, the recessing process subjected to the storage node contact plug 54 is performed through the dry etching process using a chlorine based gas in order to etch the polysilicon layer used for forming the storage node contact plug 54 faster than an oxide layer used for forming the inter-layer insulation layer 52 and a nitride layer used for forming the storage node contact spacers 53. Preferably, the chlorine based gas used in the dry etching process is chlorine (Cl₂) gas or boron trichloride (BCl₃) gas, and a recess depth D which the storage node contact plug 54 recessed from an upper portion to a lower portion of the storage node contact hole ranges from approximately 500 Å to approximately 1,000 Å.

As described above, when the polysilicon layer used for forming the storage node contact plug 54 is recessed through the dry etching process using the chlorine based gas, an etch selectivity of the polysilicon layer should be twice faster than that of the oxide layer used for forming the inter-layer insulation layer 52 and the nitride layer used for forming the storage node contact spacers 53. Thus, the dry etching process is performed by using the chlorine based gas having a higher etch selectivity with respect to the oxide layer instead of using a fluorine based gas such as a hexafluoroethane (C₂F₆) gas or a tetrafluoromethane (CF₄) gas which etches the oxide layer fast. Accordingly, only the storage node contact plug 54 can be selectively recessed.

As described above, if a result obtained by recessing the storage node contact plug 54 through the dry etching process is examined, a height difference as much as the recess depth D is generated between upper portions of the storage node contact spacers 53 and the recessed surface of the storage node contact plug 54. Since the upper portions of the storage node contact spacers 53 are placed higher than an upper portion of the storage node contact plug 54, edges of the upper portions of the storage node contact spacers 53 are exposed with a predetermined thickness.

As shown in FIG. 2C, an etch stop insulation layer 55 is formed on an entire surface including the recessed storage contact plug 54. At this time, the etch stop insulation layer 55 is formed by using a silicon nitride (Si₃N₄) layer. The etch stop insulation layer 55 has a sloped profile, and a thickness of the deposited etch stop insulation layer 55 gets gradually thinner from the upper portions of the storage node contact spacers 53 to the recessed storage node contact plug 54.

As described above, if a result obtained by the formation of the etch stop insulation layer 55 is examined, a lower structure in which the etch stop insulation layer 55 is not in a flat type but has a height difference caused by the aforementioned recessing process. Thus, the thickness of the Si₃N₄ layer used for forming the etch stop insulation layer 55 and the storage node contact spacers 53 gets different according to different lower structures of the Si₃N₄ layer.

Hereinafter, to closely examine the height difference according to the different lower structures of the Si₃N₄ layer, it is assumed that the thickness of the Si₃N₄ layer on upper portions of the inter-layer insulation layer 52 is W₁, the thickness of the Si₃N₄ layer on the upper portion of the storage contact plug 54 is W₂, and the thickness of the Si₃N₄ layer on the upper portions of the storage node contact spacers 53, i.e., the thickness from the recessed storage node contact plug 54 to the etch stop insulation layer 55 including the storage node contact spacers 53, is W₃.

Herein, among the aforementioned thicknesses W₁, W₂, and W₃, W₁ and W₂ are identical, and W₃ is thicker than W₁ and W₂. As described above, W₃ is thicker than W₁ and W₂ because the upper portions of the storage node contact spacers 53 are exposed due to the recessing process subjected to the storage node contact plug 54, and the Si₃N₄ layer is increased as much as the thickness of the upper portions of the storage node contact spacers 53.

As described above, the Si₃N₄ layer is most thickly formed on the upper portion of the storage node contact spacers 53 vulnerable to a damage during a subsequent dry etching process subjected to the etch stop insulation layer 55, and thus, it is possible to minimize an amount to be etched during the subsequent dry etching process.

As shown in FIG. 2D, an insulation layer 56 for a storage node is formed on the etch stop insulation layer 55. At this time, the insulation layer 56 is formed by using a layer selected from the consisting of a BPSG layer, an USG layer, a HDP layer, and a TEOS layer.

Next, the insulation layer 56 and the etch stop layer 55 are sequentially subjected to a dry etching process, thereby forming a trench 57 opening an upper portion of the storage node contact plug 54.

At this time, the dry etching process subjected to etch stop insulation layer 55 is employed by using a mixed base of CₓF_{y}/O₂ or CHₓF_{y}/O₂ capable of etching the Si₃N₄ layer in an oxide etcher.

During the dry etching process performed to form the trench 57, particularly during etching the etch stop insulation layer 55, an excessive etch is performed to completely open the surface of the storage node contact plug 54. At this time, an etch loss can be generated due to a damage on the storage node contact spacers 53. However, in accordance with the present invention, since the Si₃N₄ layer is thickly deposited on the upper portions of the storage node contact spacers 53 most vulnerable to the damage, it is possible to minimize the damage on the storage node contact spacers 53.

In more details about an amount of the Si₃N₄ layer etched during opening the trench 57, the amount of the Si₃N₄ layer etched on the upper surface of the storage node contact plug 54 and the upper surface of the inter-layer insulation layer 52 is limited to the thickness of the etch stop layer 55 (refer to the reference denotations W₁ and W₂ in FIG. 2C). However, at the storage node contact spacers 53 around the storage node contact plug 54, the amount of the etched Si₃N₄ layer is very thick including the thickness of the etch stop insulation layer 55 and the upper exposed portion of the storage node contact spacers 53 (refer to the reference denotation W₃ in FIG. 2C).

Accordingly, because the thickness of the Si₃N₄ layer is increased as much as the recess depth D in the portion vulnerable to the damage on the storage node contact spacers 53, although the etching process is performed until the surface of the storage node contact plug 54 is exposed during etching the etch stop insulation layer 55, the storage node contact spacers 53 are not excessively etched. Thus, an opening is not generated.

In accordance with the present invention, the Si₃N₄ layer is thickly formed on the storage node contact spacers 53 vulnerable to the damage by recessing the surface of the storage node contact plug 54 in a predetermined depth. Thus, the opening resulted from the excessive etching process subjected to the Si₃N₄ layer used for the storage node contact spacers 53 during the dry etching process of the etch stop insulation layer 55 for opening the trench 57 can be prevented, thereby obtaining a flat structure.

As shown in FIG. 2E, prior to forming a bottom electrode by using TiN, a barrier metal layer 58 is formed. For instance, Ti is deposited on an entire surface including the trench 57 through a physical vapor deposition (PVD) method or a chemical vapor deposition (CVD) method. Then, an annealing process is employed and thus, titanium silicide (TiSiₓ) is formed and non-reacted Ti is removed through a wet etching process. Titanium silicide (TiSi) which is the barrier metal layer 58 is formed by reacting silicon (Si) of the polysilicon layer used for forming the storage node contact plug 54 with titanium (Ti). Thus, TiSi is not formed on the inter-layer insulation layer 52 around the storage node contact plug 54 or on the storage node contact spacers 53.

As described above, if TiSiₓ which is the barrier metal layer 58 is formed, a resistance of a layer which the storage node contact plug 54 is contacted with a subsequent bottom electrode formed by using TiN is reduced.

Next, a storage node isolation process is performed, thereby forming a bottom electrode 59 formed by using TiN connected to the storage node contact plug 54 inside the trench 38.

In more details about the storage node isolation process to form the bottom electrode 59, TiN is deposited on the insulation layer 56 including the trench 57 trough a CVD method, a PVD method or an atomic layer deposition (ALD) method. Then, TiN formed only on an upper surface of the insulation layer 56 except for the trench 57 is removed through a CMP method or an etch-back process, thereby forming the bottom electrode 59.

Herein, there is a possibility that particles such as abrasives or etched particles are attached to the inside of the bottom electrode 59 during the CMP process or the etch-back process. Thus, the inside of the trench 57 is filled by using a photoresist layer with a good step coverage and then, TiN is subjected to the CMP process or the etch-back process until the surface of the insulation layer 52 is exposed. Afterwards, the photoresist layer is subjected to ashing.

Next, a dielectric layer 60 and a top electrode 61 formed by using TiN are sequentially formed on the bottom electrode 59, thereby forming a capacitor.

At this time, the dielectric layer 60 is formed by using a material selected from the group consisting of ONO, hafnium oxide (HfO₂), aluminum oxide (Al₂O₃), and tantalum oxide (Ta₂O₅) Since the bottom portion of the trench 57 is flat, a deposition process which is not sensitive to the step coverage can be used. Furthermore, the top electrode 61 can use a deposition process which is not sensitive to the step coverage. For instance, a CVD method, a PVD method or an ALD method is used.

In accordance with the aforementioned embodiments of the present invention, a flat structure is formed around a storage node contact plug 54 recessed during forming a dielectric layer 60 and a top electrode 61 formed by using TiN. Thus, a space in which TiN used for forming the top electrode 61 is not blocked, and a cruspidal structure is not generated on the dielectric layer 60 and the top electrode 61.

Herein, although a bottom electrode formed by using TiN is exemplified, the present invention can be applied to fabrication processes of all types of capacitors using a nitride based material to form a storage node contact spacer.

In accordance with the present invention, an etch stop insulation layer is thickly formed on a region where storage node contact spacers are vulnerable to a damage during performing a recessing process to an inter-layer insulation layer. Thus, it is possible to prevent the damage from being on the storage node contact spacers around the storage node contact plug, thereby providing an effect in improving yields of capacitors by removing a leakage current source.

As the leakage current source is removed, it is possible to obtain effects of securing a design rule according to a fine pattern and maximizing a process margin.

The present application contains subject matter related to the Korean patent application Nos. KR 2004-0114018, filed in the Korean Patent Office on Dec. 28, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a semiconductor memory device, comprising:
forming an inter-layer insulation layer having a storage node contact hole on a substrate;
forming a pair of storage node contact spacers recess to a predetermined thickness on sidewalls of the storage node contact hole;
forming a storage node contact plug surrounded by the storage node contact spacers inside the storage node contact hole;
recessing a surface of the storage node contact plug to a predetermined depth to expose upper portions of the storage node contact spacers;
forming an etch stop insulation layer on the surface of the storage node contact plug and the inter-layer insulation layer;
forming a trench opening a predetermined portion of the storage node contact plug and the storage node spacers by etching the etch stop insulation layer;
forming a bottom electrode on the trench; and
sequentially forming a dielectric layer and a top electrode on the bottom electrode.

2. The method of claim 1, wherein at the recessing of the storage node contact plug to the predetermined depth, the storage node contact plug is selectively etched by using a gas having a high etch selectivity of the storage node contact plug to the storage node contact spacers and the inter-layer insulation layer.

3. The method of claim 2, wherein the storage node contact plug is a polysilicon layer and during the recessing of the storage node contact plug, a chlorine based gas is used.

4. The method of claim 3, wherein the chlorine based gas uses one of chlorine (Cl₂) gas and boron trichloride (BCl₃) gas.

5. The method of claim 1, wherein the upper portions of the storage node contact spacers are recessed to a thickness ranging from approximately 500 Å to approximately 1,000 Å.

6. The method of claim 2, wherein the upper portions of the storage node contact spacers are recessed to a thickness ranging from approximately 500 Å to approximately 1,000 Å.

7. A method for fabricating a semiconductor memory device, comprising:
forming an inter-layer insulation layer having a storage node contact hole on a substrate;
forming a pair of storage node contact spacers on sidewalls of the storage node contact hole;
forming a storage node contact plug surrounded by the storage node contact spacers inside the storage node hole;
recessing a surface of the storage node contact plug in a predetermined depth to expose upper portions of the storage node contact spacers;
forming an etch stop insulation layer and an insulation layer for a storage node on the recessed storage node contact plug and the inter-layer insulation layer;
sequentially performing a dry etching process on the insulation layer and on the etch stop insulation layer to form a trench opening the storage node contact spacers and the storage node contact plug;
forming a bottom electrode on the trench; and
sequentially forming a dielectric layer and a top electrode on the bottom electrode.

8. The method of claim 7, wherein at the recessing of the storage node contact plug to the predetermined depth, the storage node contact plug is selectively etched by using a gas having a high etch selectivity of the storage node contact plug to the storage node contact spacers and the inter-layer insulation layer.

9. The method of claim 8, wherein the etch gas includes a chlorine based gas.

10. The method of claim 9, wherein the chlorine based gas is one of chlorine (Cl₂) gas and boron trichloride (BCl₃) gas.

11. The method of claim 7, wherein the predetermined recess depth of the storage node contact plug ranges from approximately 500 Å to approximately 1,000 Å.
